(19) United States
(12) Patent Application Publication
(10) Pub. No.: US 2024/0355688 A1
(43) Pub. Date: Oct. 24, 2024

(54) SYSTEMS AND METHODS FOR DEPOSITING MATERIAL LAYERS ONTO SUBSTRATES

(71) Applicant: ASM IP Holding B.V., Almere (NL)

(72) Inventors: Amir Kajbafvala, Chandler, AZ (US); Arun Murali, Tempe, AZ (US); Caleb Miskin, Mesa, AZ (US)

(21) Appl. No.: 18/642,877

(22) Filed: Apr. 23, 2024

Related U.S. Application Data
(60) Provisional application No. 63/461,420, filed on Apr. 24, 2023.

(51) Int. Cl. H01L 21/66; C23C 16/02; C23C 16/455; C23C 16/46; C23C 16/50; C23C 16/52; H01L 21/67

(52) U.S. Cl. CPC H01L 22/20; C23C 16/0209; C23C 16/0227; C23C 16/45544; C23C 16/46; C23C 16/50; C23C 16/52; H01L 21/67248

(57) ABSTRACT

A method for removing contaminants from an upper surface of a substrate inside various chambers of a semiconductor processing system is provided. The method may comprise heating at least a portion of the upper surface to a predetermined upper surface bake temperature to induce a chemical reaction of the contaminants with hydrogen gas in the deposition chamber and remove contaminants from the upper surface. The temperature of the bulk material forming the substrate remains substantially lower than the predetermined upper surface bake temperature. After heating the upper surface to remove the contaminants, a material layer may be deposited onto the upper surface. The semiconductor processing system and computer instructions for operating the semiconductor processing system are also described.

### CROSS-REFERENCE TO RELATED APPLICATION(S)

This Application claims the benefit of U.S. Provisional Application 63/461,420 filed on Apr. 24, 2023, the entire contents of which are incorporated herein by reference.

### FIELD OF THE DISCLOSURE

The present disclosure generally relates to making semiconductor devices. More particularly, the disclosure relates to depositing material layers onto substrates during the fabrication of semiconductor devices.

### BACKGROUND OF THE DISCLOSURE

Prior to initiating the fabrication of semiconductor devices on a semiconductor substrate in one or more reactor chambers of a semiconductor processing system or between the building of different device structures during the fabrication process, a clean surface of the substrate is desired before materials are deposited on the substrate to build the different device structures. The presence of contaminants (e.g., native oxides, interfacial oxygen, carbonaceous contaminants, hydrocarbon contaminants, moisture, etc.) on the semiconductor substrate before the deposition of a material layer onto the substrate may adversely affect the physical, mechanical and electrical properties of the formed semiconductor devices. Therefore, before beginning the fabrication of semiconductor devices and/or depositing a material layer onto a semiconductor substrate, the surface of the substrate may be cleaned by removing the contaminants from the surface of the substrate. Multiple methodologies may be used to clean a substrate surface. For example, a “wet-clean” method may use an acid (e.g., hydrofluoric acid) to remove or etch the contaminants from the substrate surface. Alternatively, a “dry-clean” method may use ionized etchants that react with and remove the contaminants from the substrate surface.

Such wet-clean and/or dry-clean methods does not always remove all the contaminants from the substrate surface. Furthermore, the surface may acquire additional contaminants after the surface of the substrate is cleaned using the wet-clean method, the dry-clean method, or both and before a material layer is deposited on the surface. For example, the surface of the substrate may acquire additional contaminants when the substrate is transferred from a dry etch chamber of a semiconductor processing system to a material deposition chamber of the semiconductor processing system. As another example, the surface of the substrate may acquire additional contaminants after the substrate undergoes a wet-clean process outside the semiconductor processing system and then loaded inside the material deposition chamber of the semiconductor processing system. Therefore, before depositing a material layer onto a substrate, the substrate may undergo a “baking” process where the substrate is heated to a high temperature (e.g., above 750° C.) for a few minutes in the presence of hydrogen gas to thermally induce a chemical reaction of the contaminants with the hydrogen gas.

While such high temperature bakes are generally effective at removing residual contaminants, the high temperature baking process may take excessive time to heat the substrate to the required temperature, perform the bake, and cool back down to the material layer deposition temperature. Furthermore, a substrate with various patterns, dielectrics, implants, and surface topographies may have a limited thermal budget. The thermal budget of a substrate may relate to the maximum time period the substrate can tolerate a high temperature before the dopant distribution and/or the thin device structures in the substrate become affected. For example, the above-described substrate may not withstand temperatures above 800° C. more than a minute or two before the electrical properties of the material layers in the substrates are affected. For example, electrical resistivity and/or sheet resistance of the material layers may be affected due to dopant migration, and the devices formed using the material layers may not function as intended. Furthermore, as the dimensions of semiconductor devices decrease, the thermal budgets of the semiconductor devices may also decrease.

Therefore, there remains a need in the art for an improved method of removing contaminants without affecting the dopant and silicon distribution in the substrates and the device structures in the substrates. The present disclosure provides a solution to this need.

### SUMMARY OF THE DISCLOSURE

A method for removing contaminants from an upper surface of a semiconductor substrate is provided. The substrate may be supported on a substrate support inside various chambers of a semiconductor processing system (e.g., an etch chamber, a material deposition chamber, etc.). The method may comprise operating the semiconductor processing system to remove the contaminants from the upper surface of the substrate. The method may include, while the substrate is in a deposition chamber, measuring, with a pyrometer, electromagnetic radiation emitted from the upper surface and heating, based on the measurement, at least a portion of the upper surface to a predetermined upper surface bake temperature to remove contaminants from the upper surface. The heating of the upper surface may be performed with a radiant heat source arranged above the deposition chamber. A bulk material temperature of a bulk material forming the substrate may remain less than the predetermined upper surface bake temperature. In this way, contaminants may be removed from the upper surface of the substrate while maintaining the substrate within its thermal budget.

In addition to one or more of the features described above, or as an alternative, further examples may include, prior to removing contaminants from the upper surface of the substrate in the deposition chamber, seating the substrate on a substrate support of a dry etch chamber and exposing, in the dry etch chamber, the upper surface of the substrate to an etchant for etching contaminants from the upper surface of the substrate. The method may further include transferring the substrate from the dry etch chamber to the deposition chamber via a substrate transfer chamber connecting the dry etch chamber and the deposition chamber.

In addition to one or more of the features described above, or as an alternative, further examples may include, after heating the upper surface to remove the contaminants in the deposition chamber, heating the substrate to a predetermined material layer deposition temperature and then depositing a material layer onto the upper surface.

In addition to one or more of the features described above, or as an alternative, further examples may include the predetermined upper surface bake temperature being above a thermal budget temperature. The electrical properties of patterned structures in the substrate may be affected when the bulk material is above the thermal budget temperature.

In addition to one or more of the features described above, or as an alternative, further examples may include that the predetermined upper surface bake temperature is between 850° C. and 1100° C.

In addition to one or more of the features described above, or as an alternative, further examples may include heating the upper surface for a time period of less than 35 seconds.

In addition to one or more of the features described above, or as an alternative, further examples may include that the radiant heat source comprises a plurality of heater elements, and that heating the upper surface comprises determining, based on the measurement of the pyrometer, an upper surface temperature of the upper surface of the substrate, and adjusting, based on a comparison of the upper surface temperature with the predetermined upper surface bake temperature, electric power applied to at least one heater element of the plurality of heater elements.

In addition to one or more of the features described above, or as an alternative, further examples may include repeating the determining of the upper surface temperature and the adjusting of the electric power to provide a closed-loop control over the heating of the upper surface of the substrate.

In addition to one or more of the features described above, or as an alternative, further examples may include that the upper surface comprises at least a first heating zone and a second heating zone. The radiant heat source may comprise one or more first heater elements disposed above the first heating zone and one or more second heater elements disposed above the second heating zone. Heating the upper surface of the substrate may comprise determining, based on the measuring with the pyrometer, a first upper surface temperature of the portion and determining, based on measuring second electromagnetic radiation emitted from the second portion with a second pyrometer, a second upper surface temperature of the second portion. Then, based on a comparison of the first upper surface temperature with the predetermined upper surface bake temperature, first electric power applied to the one or more first heater elements may be adjusted, and based on a comparison of the second upper surface temperature with the second predetermined upper surface bake temperature, second electric power applied to the one or more second heater elements may be adjusted.

In addition to one or more of the features described above, or as an alternative, further examples may include that the contaminants removed from the upper surface of the substrate include contaminants deposited on the upper surface during the transfer between the etch chamber and the deposition chamber and/or contaminants deposited on the upper surface prior to seating the substrate on a substrate support of the dry etch chamber.

A semiconductor processing system for processing a substrate to form semiconductor devices is provided. The semiconductor processing system may comprise a dry etch chamber, a deposition chamber, a radiant heat source arranged above the deposition chamber, a substrate transfer chamber connecting the dry etch chamber and the deposition chamber, a pyrometer configured to measure electromagnetic radiation emitted from an upper surface of a substrate present in the deposition chamber, and/or one more controllers. The one or more controllers may be configured to support the substrate on a substrate support in the dry etch chamber, expose, in the dry etch chamber, the upper surface of the substrate to an etchant for etching the upper surface, and transfer, via the substrate transfer chamber, the substrate from the dry etch chamber to the deposition chamber. While the substrate is in the deposition chamber, the one or more controllers may be further configured to control, based on a measurement from the pyrometer, the radiant heat source to heat the upper surface to a predetermined upper surface bake temperature to remove contaminants from the upper surface, while a bulk material temperature of a bulk material forming the substrate remains less than the predetermined upper surface bake temperature. After heating the upper surface to remove the contaminants, the one or more controllers may be configured to heat the substrate to a predetermined material layer deposition temperature and deposit a material layer onto the upper surface.

In addition to one or more of the features described above, or as an alternative, further examples may include that the one or more controllers are configured to maintain the bulk material temperature to be below a thermal budget temperature at which electrical properties of patterned structures in the substrate are affected by the bulk material being above the thermal budget temperature.

In addition to one or more of the features described above, or as an alternative, further examples may include that the predetermined upper surface bake temperature is between 850° C. and 1100° C.

In addition to one or more of the features described above, or as an alternative, further examples may include that the one or more controllers are configured to control the radiant heat source to heat the upper surface to the predetermined upper surface bake temperature within a time period of less than 35 seconds.

In addition to one or more of the features described above, or as an alternative, further examples may include that the radiant heat source comprises a plurality of heater elements. The one or more controllers may be configured to determine, based on the measurement from the pyrometer, an upper surface temperature of the upper surface, and adjust, based on a comparison of the upper surface temperature with the predetermined upper surface bake temperature, electric power applied to at least one heater element of the plurality of heater elements.

In addition to one or more of the features described above, or as an alternative, further examples may include that the one or more controllers are configured to repeat the determining of the upper surface temperature and the adjusting of the electric power to provide a closed-loop control over the heating of the upper surface.

A non-transitory computer readable medium is provided, where the non-transitory computer readable medium stores instructions that, when executed by one or more processors of a semiconductor processing system, cause the semiconductor processing system to support a substrate on a substrate support in a dry etch chamber, expose, in the dry etch chamber, an upper surface of the substrate to an etchant for etching the upper surface, and transfer the substrate from the dry etch chamber to a deposition chamber via a substrate transfer chamber connecting the dry etch chamber and the deposition chamber. While the substrate is in the deposition chamber, the instructions that, when executed by the processors of the semiconductor processing system, may cause the semiconductor processing system to measure, with a pyrometer, electromagnetic radiation emitted from the upper surface, and control, based on the measuring with the pyrometer, a radiant heat source, arranged above the deposition chamber, to heat the upper surface to a predetermined upper surface bake temperature to remove contaminants from the upper surface, while a bulk material temperature of a bulk material forming the substrate remains less than the predetermined upper surface bake temperature. After heating the upper surface to remove the contaminants, the executed instructions may cause the semiconductor processing system to heat the substrate to a predetermined material layer deposition temperature and deposit a material layer onto the upper surface.

In addition to one or more of the features described above, or as an alternative, further examples may include that the instructions, when executed by the processors of the semiconductor processing system, may cause the semiconductor processing system to heat the upper surface for a time period of less than 35 seconds.

In addition to one or more of the features described above, or as an alternative, further examples may include that the predetermined upper surface bake temperature is between 850° C. and 1100° C.

In addition to one or more of the features described above, or as an alternative, further examples may include that the executed instructions may cause the semiconductor processing system to maintain the bulk material temperature to be below a thermal budget temperature at which electrical properties of patterned structures in the substrate are affected by the bulk material being above the thermal budget temperature.

In addition to one or more of the features described above, or as an alternative, further examples may include that the radiant heat source comprises a plurality of heater elements and that the instructions, when executed by the processors of the semiconductor processing system, cause the semiconductor processing system to determine, based on the measuring with the pyrometer, an upper surface temperature of the upper surface and adjust, based on a comparison of the upper surface temperature with the predetermined upper surface bake temperature, electric power applied to at least one heater element of the plurality of heater elements.

In addition to one or more of the features described above, or as an alternative, further examples may include that the radiant heat source comprises a plurality of heater elements and that the instructions, when executed by the processors of the semiconductor processing system, cause the semiconductor processing system to repeat the determining of the upper surface temperature and the adjusting the electric power to provide a closed-loop control over the heating of the upper surface.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

Features, aspects, and advantages of the invention disclosed herein are described below with reference to the drawings of certain embodiments, which are intended to illustrate and not limit the invention.

FIG. 1 illustrates an exemplary embodiment of a semiconductor processing system according to various aspects of the present disclosure.

FIG. 2 is a schematic view of a semiconductor processing system chamber in accordance with the present disclosure, showing a precursor delivery arrangement connected to an exhaust arrangement via the material deposition chamber.

FIGS. 3 and 4 are schematic side and top views of the reactor chamber of FIG. 2 according to a first example of the present disclosure, showing a pyrometer operatively connected to an upper radiant heat source of the material deposition chamber.

FIGS. 5 and 6 are schematic side and top views of the reactor chamber of FIG. 2 according to a second example of the present disclosure, showing three pyrometers operatively connected to an upper radiant heat source of the reactor chamber.

FIGS. 7, 8, and 9 are block diagrams of an example method for heating an upper surface of a substrate and removing contaminants from the upper surface in accordance with the present disclosure, showing operations of the method according to an illustrative and non-limiting example of the present disclosure.

FIG. 10 is a control schematic of a semiconductor processing system, including temperature monitoring components and a controller configured to provide multi-zone control of the upper radiant heat source.

FIG. 11 shows the heating profiles of an upper surface and a bottom surface of a substrate.

FIG. 12 illustrates the tunability of the temperatures of the upper surfaces of substrates.

FIG. 13 illustrates the repeatability of the upper radiant heat source in achieving the same upper surface temperature.

It will be appreciated that elements in the figures are illustrated for simplicity and clarity and have not necessarily been drawn to scale. For example, the relative size of some of the elements in the figures may be exaggerated relative to other elements to help improve the understanding of illustrated embodiments of the present disclosure.

### DETAILED DESCRIPTION OF EXEMPLARY EMBODIMENTS

Described herein is an improved and faster baking method for removing contaminants from substrates before depositing materials onto a substance and/or after cleaning the substrate by the wet-clean method, the dry-clean method, or both. The traditional baking process may require time to heat the entire substrate (e.g., using heat sources disposed above and below the substrate), cool down the substrate to the material deposition temperature, and wait for complete stabilization (e.g., thermal and/or positional stabilization of the atoms in the substrate) of the surface atoms to occur. The improved and faster baking method may comprise heating, with a heat source disposed above the surface, the upper surface of the substrates (e.g., just the contaminants and a small portion of the semiconductor substrate below the contaminants) at least up to an upper surface bake temperature (e.g., above 850° C.) such that a chemical removal of the contaminants can be performed (e.g., with hydrogen (H₂) gas) within seconds (e.g., between 4 and 35 seconds). When compared to the traditional baking process, a much smaller amount of heat may be provided (e.g., with a heat source disposed below the substrate) to the rest of the portion of the substrate during the improved baking process such that the bulk of the substrate is substantially below the upper surface bake temperature. Therefore, after the improved baking process, the rest of the portion of the substrate may cool down or stabilize back to the material deposition temperature much faster. The improved baking process may remove contaminants from the upper surface of the substrate on the order of seconds (e.g., 4 to 35 seconds), while a traditional bake of the substrate (e.g., heat the entire substrate to a high temperature) may require minutes (e.g., one to two minutes or more). By switching from the traditional baking process of the entire substrate to the improved baking method, the fabrication process of the substrates may become faster, resulting in a 25-40% improvement in the throughput of the fabrication process.

Furthermore, during the improved baking process, the temperature of the bulk of the substrate may be substantially below a thermal budget temperature (e.g., the temperature at which electrical properties of patterned structures in the substrate and dopants in the substrate are affected by the substrate being above that temperature). Therefore, the improved baking method for contamination removal may also result in reduced usage of the thermal budget of the substrates.

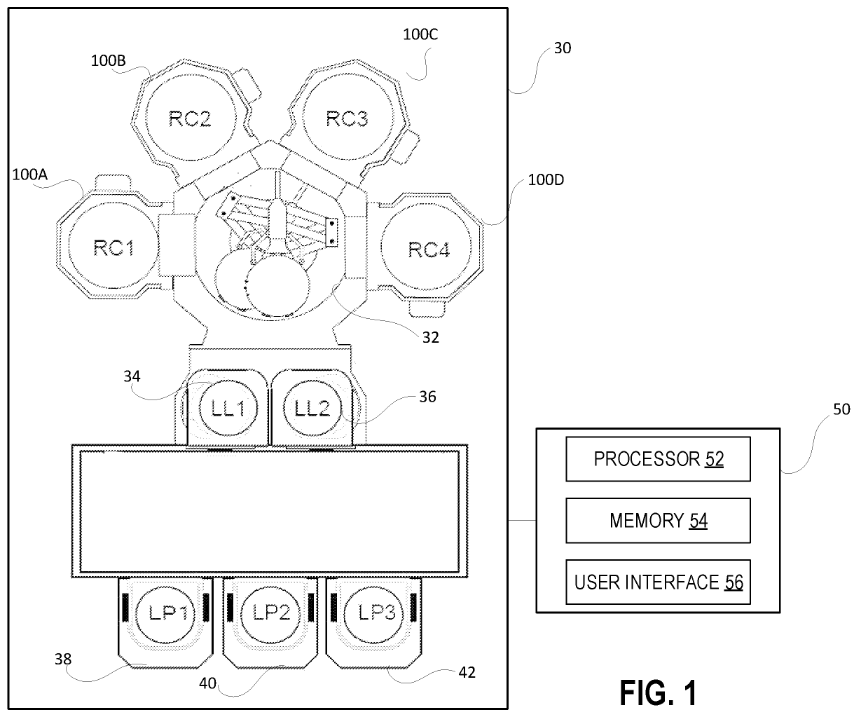

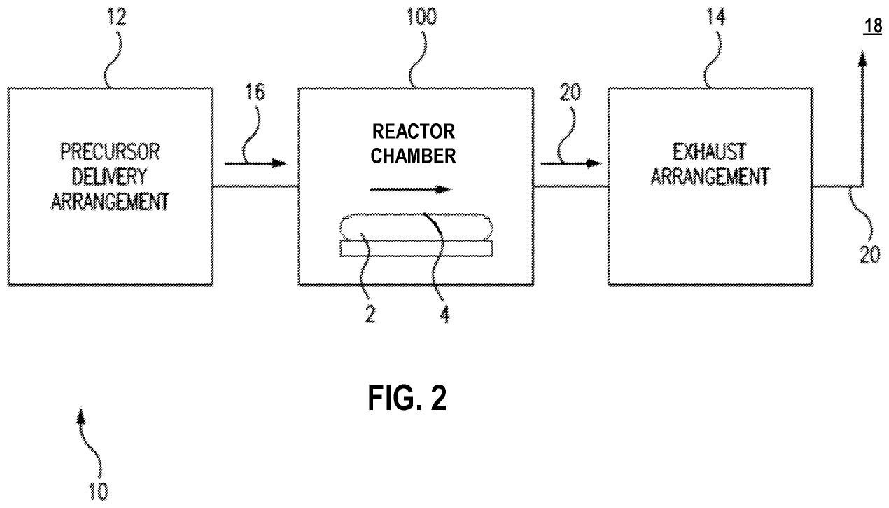

Reference will now be made to the drawings wherein like reference numerals identify similar structural features or aspects of the subject disclosure. For purposes of explanation and illustration, and not limitation, a partial view of an example of a silicon semiconductor processing system in accordance with the present disclosure is shown in FIG. 1 and is designated generally by reference character 30. Other examples of semiconductor processing systems and methods of removing contaminants from substrate surfaces in accordance with the present disclosure, or aspects thereof, are provided in FIGS. 2-13, as will be described. The systems and methods of the present disclosure can be used to control the temperature of the upper surface of the substrate and the temperature of the rest of the portion of the substrate during the removal of contaminants from the upper surface, such as before initiating the fabrication of semiconductor devices or before the deposition of epitaxial material layers onto substrates during the fabrication.

An exemplary semiconductor processing system 30 is depicted in FIG. 1. The system may include a left load lock chamber (LL1) 34, a right load lock chamber (LL2) 36, a substrate transfer chamber 32, a first reactor chamber (RC1) 100A, a second reactor chamber (RC2) 100B, a third reactor chamber (RC3) 100C, a fourth reactor chamber (RC4) 100D, a first load port (LP1) 38, a second load port (LP2) 40, and a third load port (LP3) 42. Embodiments of the present disclosure may include, or operate in conjunction with, other semiconductor processing systems, which may include more, fewer, or different components than shown in FIG. 1.

The load lock chambers 34, 36 in the exemplary system 100 are intermediary chambers in communication with the substrate transfer chamber 32 and the load ports 38, 40, 42. In some processes, the load lock chambers 34, 36 may facilitate the transfer of substrates between the substrate transfer chamber 32 under vacuum conditions and the load ports 38, 40, 42 under ambient or atmospheric pressure. The substrate transfer chamber 32 includes a robot for transferring substrates between the load lock chambers 34, 36 and the reactor chambers 100A, 100B, 100C, 100D.

Substrates may be loaded into the reactor chambers 100A, 100B, 100C, 100D and processed. Various substrate processing methods may include dry-clean methods, etching the substrate to form device structures, and/or methods for forming a thin material film on a substrate, including vacuum evaporation deposition, molecular beam epitaxy, variants of Chemical Vapor Deposition (CVD) (including low-pressure CVD, organometallic CVD, and plasma-enhanced CVD) and Atomic Layer Epitaxy (ALE). ALE may also be referred to as Atomic Layer Deposition (ALD). In some examples, one of the reactor chambers 100A, 100B, 100C, 100D may be used for cleaning substrates using dry-clean methods, while another one of the reactor chambers 100A, 100B, 100C, 100D may be used for depositing thin material films.

Depending on the type of semiconductorprocess(es) employed, various gasses may be pumped into, and removed from, the reactor chambers 100A, 100B, 100C, 100D. The temperature and/or pressure within the reactor chambers 100A, 100B, 100C, 100D (or portions thereof) may also be raised or lowered.

The functionality of the semiconductor processing system 30, as well as any other component operating in conjunction with embodiments of the present disclosure, can be implemented in any suitable manner, such as through a processor executing software instructions stored in a memory. Functionality may also be implemented through various hardware components storing machine-readable instructions, such as application-specific integrated circuits (ASICs), field-programmable gate arrays (FPGAs), and/or complex programmable logic devices (CPLDs).

In the exemplary system depicted in FIG. 1, some or all of the functionality of the semiconductor processing system 30 can be controlled via control system 50, which includes a processor 52, memory 54, and a user interface 56. Individual components of the semiconductor processing system 30 (such as the robot in the semiconductor transfer chamber 32) may also be controlled by other software or hardware components. Portions of control system 50 may be integrated with, or remote from, the semiconductor processing system 30.

The processor 52 retrieves and executes instructions stored in the memory 54 to control various portions of the semiconductor processing system 30. Any number and type of processor(s), such as an integrated circuit microprocessor, microcontroller, and/or digital signal processor (DSP), can be used in conjunction with embodiments of the present disclosure. The processor 52 may include, or operate in conjunction with, any other suitable components and features, such as comparators, analog-to-digital converters (ADCs), and/or digital-to-analog converters (DACs).

The memory 54 may be capable of storing executable instructions, data transmitted to or received from the components of semiconductor processing system 30, and other information. The memory 54 may include any combination of different transitory and non-transitory memory storage devices, such as hard drives, random access memory (RAM), read-only memory (ROM), FLASH memory, or any other type of volatile and/or nonvolatile memory. Software for controlling the functionality of a semiconductor processing system operating in conjunction with embodiments of the present disclosure may include safeguards to prevent resource collisions and/or damage to wafers or components of the system. For example, in some exemplary embodiments, software for controlling a semiconductor processing tool may include one or more semaphores to prevent the processing tool from performing a first action until a second action is completed in cases where the first and second actions cannot, or should not, be performed simultaneously.

The control system 50 may include an operating system (e.g., Windows, OS2, UNIX, Linux, Solaris, MacOS, etc.) as well as various conventional support software and drivers typically associated with computers. Software applications stored in the memory may be entirely or partially served or executed by the processor(s) in performing methods or processes of the present disclosure.

The control system 50 includes a user interface 56 to allow a user to communicate with the semiconductor processing system 30. The user interface may include any number of input devices such as a keyboard, mouse, touchpad, touch screen, alphanumeric keypad, voice recognition system, or other input devices to allow a user to provide instructions and information to other components in a system of the present disclosure. Similarly, the user interface may include any number of suitable output devices, such as a monitor, speaker, printer, or other devices for providing information to one or more users. While various embodiments may be performed in semiconductor processing system 30, other embodiments may include a similar system with more or less reactor chambers, load lock chambers or load ports, or may include individual reactor chambers separate from an integrated system, or may include a single reactor chamber.

With reference to FIG. 2, an example reactor system 10 (e.g., a system for any one of the reactor chambers 100A, 100B, 100C, 100D) is shown. The reactor system 10 may include a precursor delivery arrangement 12, the reactor chamber 100 (e.g., any one of the reactor chambers 100A, 100B, 100C, 100D), and an exhaust arrangement 14. The precursor delivery arrangement 12 may be connected to the reactor chamber 100 and configured to provide a precursor 16 to the reactor chamber 100. For a reactor chamber performing dry-clean methods, the precursor 16 may be, for example, hydrogen radicals, fluorine radicals, and/or chlorine radicals. The etchant delivery arrangement 12 may produce, for example, the hydrogen radicals (e.g., from hydrogen (H₂), ammonia (NH₃), or water (H₂O)), the fluorine radicals (e.g., from nitrogen trifluoride (NF₃), trifluoromethyl (CF₄), hexafluoroethane (C₂F₆), hexafluorobutadine (C₄F₆), octafluorocyclobutane (C₄F₅), carbonyl fluoride (COF₂), sulfur hexafluoride (SF₆), hydrogen fluoride (HF), fluorine (F₂), or tungsten hexafluoride (WF₆)) and/or the chlorine radicals (e.g., chlorine (Cl₂), hydrogen chloride (HCl)). For a reactor chamber performing material deposition, the precursor 16 may comprise radicals of materials that will be deposited on the substrate. The reactor chamber 100 may be connected to the exhaust arrangement 14. The exhaust arrangement 14 may be in fluid communication with the environment 18 external to the reactor system 10 and be configured to communicate a flow of residual precursor and/or reaction products 20 to the environment 18 external to the reactor system 10. The exhaust arrangement 14 may be configured to evacuate the reactor chamber 100 and, in this respect, may include one or more vacuum pumps and/or an abatement apparatus. The one or more vacuum pumps may be connected to the reactor chamber 100 and configured to control pressure within the reactor chamber 100. The abatement apparatus may be connected to the one or more vacuum pumps and configured to process the flow of residual precursor and/or reaction products 20 issued by the reactor chamber 100. It is contemplated that the exhaust arrangement 14 may be configured to maintain environmental conditions within the reactor chamber 100 suitable for atmospheric contamination removal and material deposition operations, such as pressures between about 2 torrs and about 760 torrs.

As used herein, the term “substrate” may refer to any underlying material or materials that may be used, or upon which, a device, a circuit, or a film may be formed. The “substrate” may be continuous or non-continuous, rigid or flexible, and/or solid or porous. The substrate may be in any form, such as a powder, a plate, or a workpiece. Substrates in the form of a plate may include wafers, e.g., 300-millimeter silicon wafers, in various shapes and sizes. Substrates may be made from materials, such as silicon, silicon germanium, silicon oxide, gallium arsenide, gallium nitride, and silicon carbide by way of non-limiting examples. A continuous substrate may extend beyond the bounds of a process chamber where a deposition process occurs and may move through the reactor chamber such that the process continues until the end of the substrate is reached. A continuous substrate may be supplied from a continuous substrate feeding system, enabling the manufacture and output of the continuous substrate in any appropriate form.

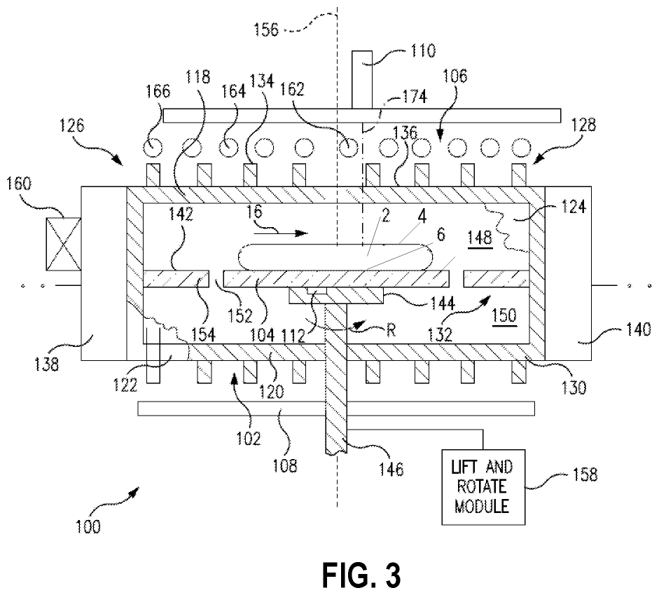

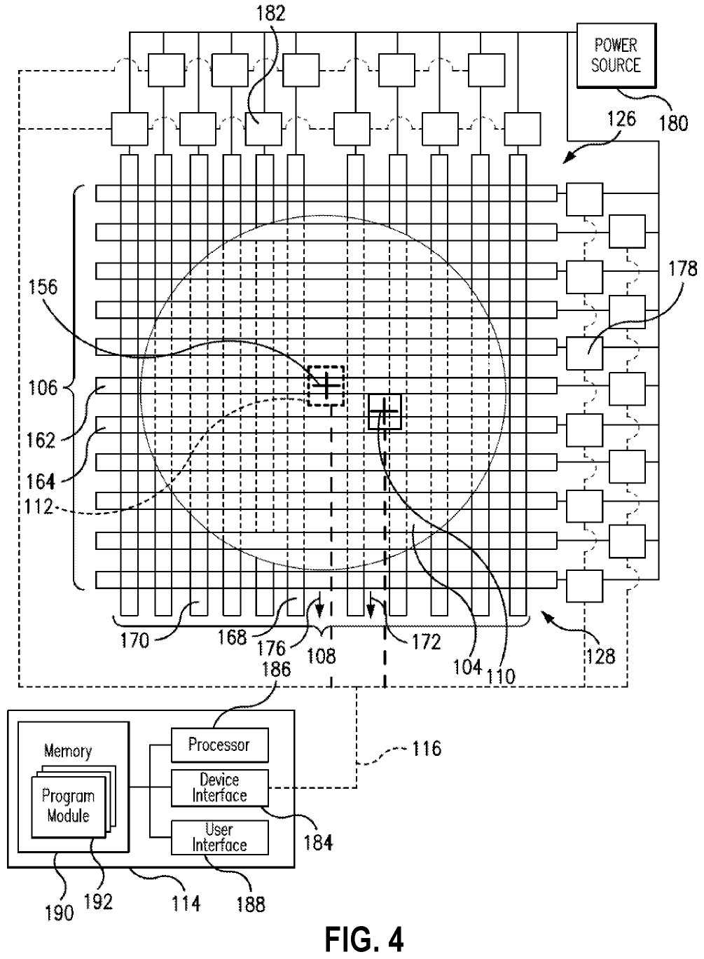

With reference to FIG. 3, the reactor chamber 100 is shown. The reactor chamber 100 may include a chamber body 102 and a substrate support 104 (e.g., susceptor, spherical platform, pedestal, column, etc., for supporting a substrate inside the reactor chamber 100). The reactor chamber 100 may also include an upper heat source 106 and a lower heat source 108. The reactor chamber 100 may further include a pyrometer 110, a thermocouple 112, a controller 114 (shown in FIG. 4 and/or may be the same the control system 50 or a separate controller), and a wired or wireless link 116 (shown in FIG. 4). Although a specific arrangement is shown and described herein, it is to be understood and appreciated that the reactor chamber 100 may include other elements and/or omit elements shown and described herein and remain within the scope of the present disclosure.

The chamber body 102 may be configured to flow the precursor 16 onto or across the substrate 2 and may have an upper wall 118, a lower wall 120, a first sidewall 122, and a second sidewall 124. The upper wall 118 may extend longitudinally between an injection end 126 and a longitudinally opposite exhaust end 128 of the chamber body 102, be supported horizontally relative to gravity, and be formed from a transmissive material 130. The lower wall 120 may be below and parallel relative to the upper wall 118 of the chamber body 102, spaced apart from the upper wall 118 by an interior 132 of the chamber body 102, and formed from the transmissive material 130. The first sidewall 122 may longitudinally span the injection end 126 and the exhaust end 128 of the chamber body 102, extend vertically between the upper wall 118 and the lower wall 120 of the chamber body 102, and form from the transmissive material 130. The second sidewall 124 may be parallel to the first sidewall 122, laterally opposite, spaced apart from the first sidewall 122 by the interior 132 of the chamber body 102, and formed from the transmissive material 130. In certain examples, the transmissive material 130 may include a ceramic material such as sapphire or quartz. In accordance with certain examples, the chamber body 102 may include a plurality of external ribs 134. The plurality of external ribs 134 may extend laterally about an exterior 136 of the chamber body 102 and be longitudinally spaced between the injection end 126 and the exhaust end 128 of the chamber body 102. In certain examples, the one or more of the walls 118 and 120 may be substantially planar. In accordance with certain examples, one or more of the walls 118 and 120 may be arcuate or dome-like in shape. It is also contemplated that, in accordance with certain examples, the chamber body 102 may include no ribs.

An injection flange 138 and an exhaust flange 140 may be connected to the injection end 126 and the exhaust end 128, respectively, of the chamber body 102. The injection flange 138 may fluidly couple the precursor delivery arrangement 12 (shown in FIG. 2) to the interior 132 of the chamber body 102 and be configured to provide the precursor 16 to the interior 132 of the chamber body 102. The exhaust flange 140 may fluidly couple the interior 132 of the chamber body 102 to the exhaust arrangement 14. The exhaust flange 140 may be configured to communicate the residual precursor and/or reaction products 20 (shown in FIG. 2) issued by the reactor chamber 100 during the removal of contaminants from the upper surface 4 of the substrate 2. In this respect, the chamber body 102 may have a cold wall, cross-flow reactor configuration.

A divider 142, a support member 144, and a shaft member 146 may be arranged within the interior 132 of the chamber body 102. The divider 142 may be fixed within the interior 132 of the chamber body 102 and divide the interior 132 of the chamber body 102 into an upper chamber 148 and a lower chamber 150. The divider 142 may further define an aperture 152, and the aperture 152 may fluidly couple the upper chamber 148 of the chamber body 102 to the lower chamber 150 of the chamber body 102. The divider 142 may be formed from an opaque material 154. The opaque material 154 may include silicon carbide.

The substrate support 104 may be configured to sit thereon the substrate 2 and supported at least partially within the aperture 152 for rotation R about a rotation axis 156. The substrate support 104 may seat the substrate 2 such that a radially-outer peripheral of the substrate 2 abuts the substrate support 104 while a radially-inner central portion of the substrate 2 is spaced apart from the substrate support 104. The support member 144 may be arranged below the substrate support 104 and along the rotation axis 156. The support member 144 may be further arranged within the lower chamber 150 of the chamber body 102, and fixed in rotation relative to the substrate support 104 about the rotation axis 156 for rotation with the substrate support 104. The substrate support 104 may be formed from an opaque material, such as the opaque material 154 or a graphite material. The support member 144 may be formed from a transmissive material, such as the transmissive material 130.

The shaft member 146 may be arranged along the rotation axis 156 and fixed in rotation relative to the support member 144 about the rotation axis 156. The shaft member 146 may also extend through the lower chamber 150 of the chamber body 102 and through the lower wall 120 of the chamber body 102. The shaft member 146 may further operably connect a lift and rotate module 158 to the substrate support 104. The lift and rotate module 158 may in turn be configured to rotate R the substrate support 104 and the substrate 2 about the rotation axis 156 during the removal of the contaminants from the upper surface 4 of the substrate 2. The lift and rotate module 158 may further cooperate with a gate valve 160 and a lift pin arrangement to seat and unseat the substrate 2 from the substrate support 104, such as through a substrate handling robot arranged within a cluster-type platform in selective communication with the interior 132 of the chamber body 102 through the gate valve 160. In certain examples, the shaft member 146 may be formed from a transmissive material, such as the transmissive material 130.

The upper heat source 106 may be configured to heat the substrate 2 from the upper surface of the substrate by radiantly communicating heat into the upper chamber 148 of the chamber body 102. In this respect, the upper heat source 106 may include a first upper heater element 162, a second upper heater element 164, and at least one third upper heater element 166. The first upper heater element 162 may include a linear filament and a quartz tube enclosing the linear filament and/or may include one or more bulb or lamp-type heater elements. The first upper heater element 162 may be supported above the upper wall 118 of the chamber body 102, may extend laterally between the first sidewall 122 and the second sidewall 124 of the chamber body 102, and may further overlay the substrate support 104. The second upper heater element 164 and the at least one third upper heater element 166 may be similar to the first upper heater element 162, may additionally be longitudinally spaced apart from the first upper heater element 162, and may further be longitudinally spaced apart from the rotation axis 156. The second upper heater element 164 may further overlay (e.g., intersect) a peripheral edge of the substrate 2. The at least one third upper heater element 166 may overlay the divider 142. In certain examples, the upper heat source 106 may comprise between two (2) and twelve (12) upper heater elements. Each upper heater element of the upper heat source 106 may be longitudinally spaced apart from one another above the upper wall 118 of the chamber body 102 between the injection end 126 and the exhaust end 128 of the chamber body 102.

With reference to FIG. 4, the lower heat source 108 may be similar to the upper heat source 106 and may also be configured to heat the substrate 2 (shown in FIG. 2) from the bottom surface 6 of the substrate. In this respect, the lower heat source 108 may be configured to communicate radiant heat into the lower chamber 150 (shown in FIG. 3) of the chamber body 102 (shown in FIG. 3) to the substrate support 104 (shown in FIG. 3) and the divider 142 (shown in FIG. 3). The substrate support 104 and the divider 142 may in turn heat the substrate 2 by conducting the heat through the bulk material forming the substrate support 104 and the divider 142, radiant heat communicated into the lower chamber 150 by the lower heat source 108 thereby being conducted to the substrate 2. The lower heat source 108 may include a first lower heater element 168 and at least one second lower heater element 170.

The first lower heater element 168 may be similar to the first upper heater element 162 and may be additionally supported below the lower wall 120 (shown in FIG. 3) of the chamber body 102 (shown in FIG. 3). The upper heating elements may be configured to directly radiate heat to the upper surface of a substrate seated on the substrate support 104. The first lower heater element 168 further extends longitudinally between the injection end 126 (shown in FIG. 3) and the exhaust end 128 (shown in FIG. 3) of the chamber body 102. The first lower heater element 168 may further be substantially orthogonal or parallel relative to the first upper heater element 162 of the upper heat source 106. The at least one second lower heater element 170 may be parallel to the first lower heater element 168 and laterally spaced apart from the first lower heater element 168 below the lower wall 120 (shown in FIG. 3) of the chamber body 102. In certain examples, the first lower heater element 168 may underlie the substrate support 104. In accordance with certain examples, the at least one second lower heater element 170 may underlie the divider 142 (shown in FIG. 3). It is also contemplated that, in accordance with certain examples, the lower heat source 108 may include between two (2) and twelve (12) lower heater elements each laterally spaced apart from one another below the lower wall 120 of the chamber body 102.

The pyrometer 110 may be configured to acquire an optical temperature measurement 172 using electromagnetic radiation emitted by the upper surface 4 of the substrate 2 (shown in FIGS. 2 and 3). In this respect, the pyrometer 110 may be supported above the upper wall 118 (shown in FIG. 3) of the chamber body 102 (shown in FIG. 3) and is arranged along an optical axis 174 (shown in FIG. 3). More specifically, the pyrometer 110 may be supported above the upper heat source 106 and arranged longitudinally between the injection end 126 and the exhaust end 128 of the chamber body 102 such that the optical axis 174 may extend between the first upper heater element 162 and the second upper heater element 164. The optical axis 174 may further intersect the substrate support 104. The optical axis 174 may intersect the substrate 2 when seated on the substrate support 104. The optical temperature measurement 172 may be thereby acquired directly from the upper surface 4 of the substrate 2 by pyrometer 110. In certain examples, the optical axis 174 may be coaxial with the rotation axis 156. In accordance with certain examples, the pyrometer 110 may at least one of longitudinally offset and/or laterally offset from the rotation axis 156, e.g., radially offset from the rotation axis 156. As will be appreciated by those of skill in the art in view of the present disclosure, offsetting the optical axis 174 from the rotation axis 156 may facilitate packaging the pyrometer 110 above the chamber body 102. Examples of suitable pyrometers include OR400M optical infrared pyrometers, available from the Advanced Energy Corporation of Denver, Colorado.

The thermocouple 112 may be configured to acquire the temperature of the substrate support 104 and provide a tactile temperature measurement 176 indicative of the temperature of the substrate support 104. In this respect the thermocouple 112 may be arranged within the interior 132 (shown in FIG. 3) of the chamber body 102 (shown in FIG. 3). More specifically, the thermocouple 112 may be arranged within the lower chamber 150 (shown in FIG. 3) of the chamber body 102 and fixed in rotation R relative to the substrate support 104. Specifically, the thermocouple 112 may be in intimate mechanical contact (e.g., abut) with a lower surface of the substrate support 104. The thermocouple 112 may be arranged along the rotation axis 156. The thermocouple 112 may be offset from the rotation axis 156, for example, radially offset from the rotation axis 156, such that the thermocouple 112 underlies the pyrometer 110, potentially improving the accuracy of either (or both) the optical temperature measurement 172 provided by the pyrometer 110 and a tactile temperature measurement 176 provided by the thermocouple 112. Examples of suitable thermocouples may include those shown and described in U.S. Pat. No. 7,874,726 B2 to Jacobs et al., issued Jan. 25, 2011, the contents of which are incorporated herein by reference in its entirety.

The controller 114 may be connected to the upper heat source 106 and the lower heat source 108. In this respect, the wired or wireless link 116 may connect the controller 114 to the upper heat source 106 and the lower heat source 108. In certain examples, one or more upper switches or control devices 178 (e.g., silicon-controlled rectifier (SCR) devices) may couple the controller 114 to the upper heat source 106. In accordance with certain examples, a singular one of the one or more upper SCR device 178 couple each of the upper heater elements of the upper heat source 106 to both the controller 114 and a power source 180, the controller 114 may thereby have discrete control over power applied to each of the upper heater elements of the upper heat source 106. The lower heat source 108 may be similarly throttled, one or more lower SCR device 182 coupling the controller 114 to the lower heater elements of the lower heat source 108. The one or more lower SCR devices 182 may include a singular lower SCR device coupling the each of the lower heater elements of the lower heat source 108 to both the controller 114 and the power source 180 to provide discrete control over power applied to each of the lower heater elements of the lower heat source 108.

It is contemplated that the controller 114 may be connected to the pyrometer 110 and/or the thermocouple 112, for example, by the wired or wireless link 116. In this respect, the controller 114 may operatively connect the pyrometer 110 to the upper heat source 106, and power applied to (and thereby radiant heat output) from the upper heat source 106 be controlled or adjusted according to the optical temperature measurement 172 provided to the controller 114 by the pyrometer 110. The controller 114 may also operatively connect the thermocouple 112 to the lower heat source 108, and power applied to the lower heat source 108 be controlled or adjusted by the tactile temperature measurement 176 provided to the controller 114 by the thermocouple 112.

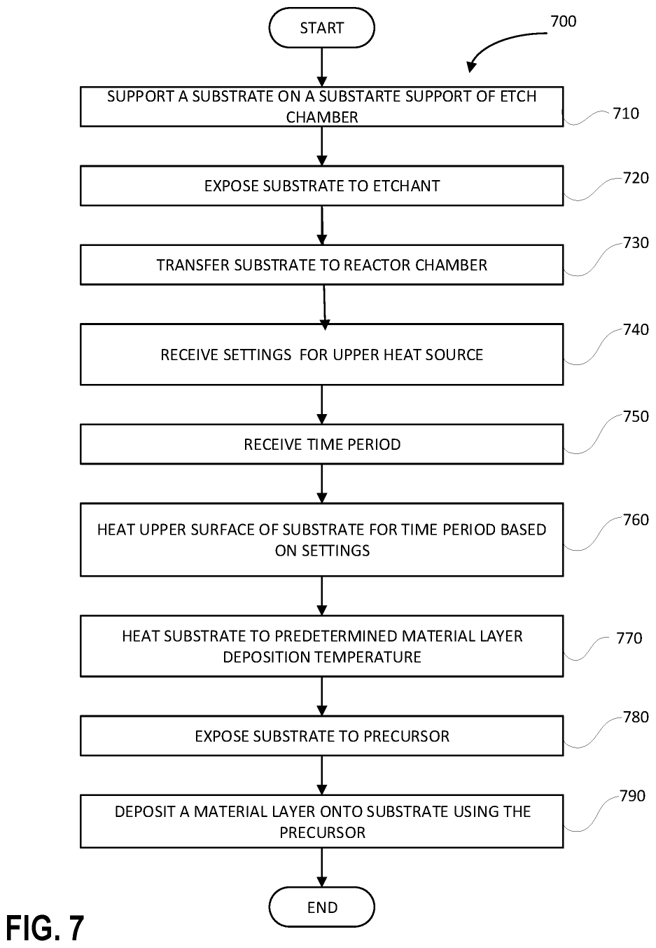

In the illustrated example, the controller 114 may include a device interface 184, a processor 186, a user interface 188, and a memory 190. The device interface 184 may connect the processor 186 to the wired or wireless link 116. The processor 186 may be operably connected to the user interface 188 (e.g., to receive user input and/or provide user output therethrough) and may be disposed in communication with the memory 190. The memory 190 may include a non-transitory machine-readable medium having a plurality of program modules 192 recorded thereon containing instructions that, when read by the processor 186, cause the processor 186 to execute certain operations. Among the operations are operations of a contaminant removal method 600 (shown in FIG. 7), as will be described. As will be appreciated by those of skill in the art in view of the present disclosure, the controller 114 may have a different arrangement in other examples and remain within the scope of the present disclosure.

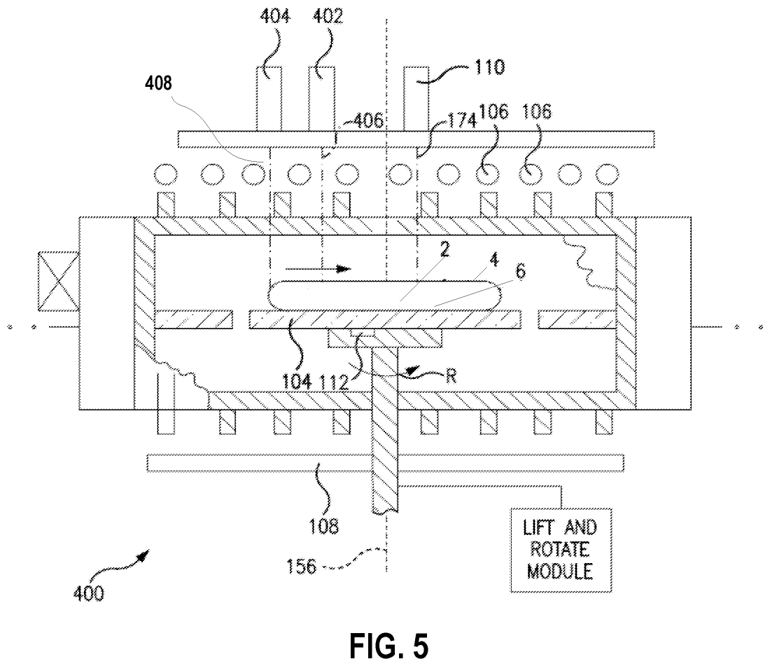

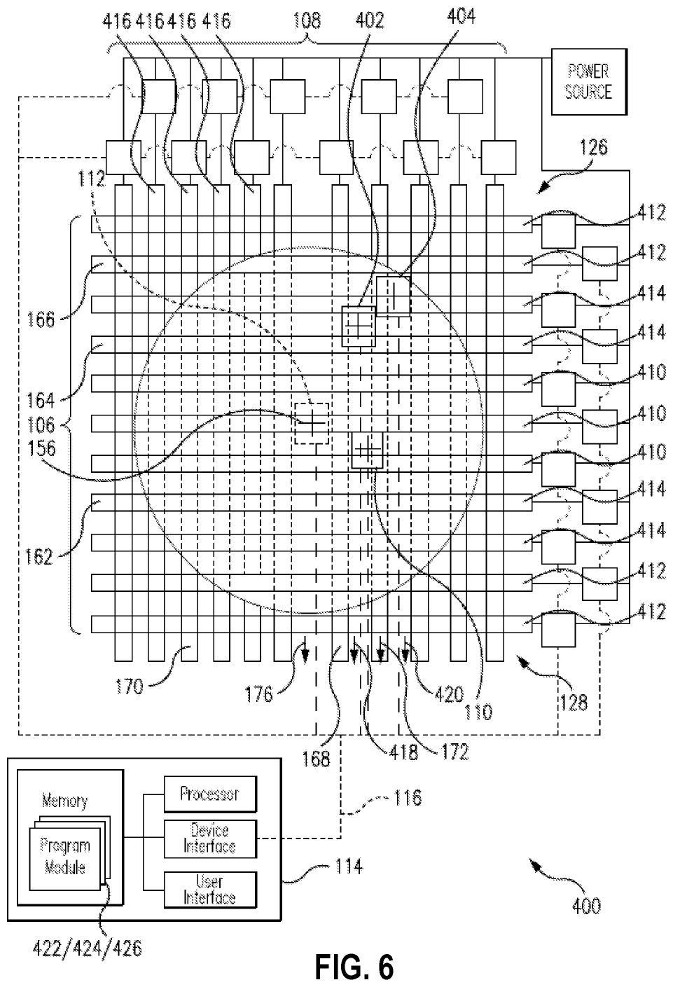

With reference to FIGS. 5 and 6, a reactor chamber 400 is shown. The reactor chamber 400 may be similar to the reactor chamber 100 (shown in FIGS. 2, 3, and 4) and additionally may include a second pyrometer 402 and a third pyrometer 404. The second pyrometer 402 may be supported above the upper heat source 106 and along a second optical axis 406. The second optical axis 406 may be radially outwards of the first optical axis 174, overlay the substrate support 104, and intersects the substrate 2 when the substrate 2 is seated on the substrate support 104. The second optical axis 406 may be parallel to the first optical axis 174 and may further extend between the first upper heater element 162 and the at least one third upper heater element 166. The third pyrometer 404 may also be supported above the upper heat source 106, arranged along a third optical axis 408 and parallel to the second optical axis 406. The third optical axis 408 may be radially intermediate to the first optical axis 174, and the second optical axis 406, the third optical axis 408 may also overlay the substrate support 104 and intersect the substrate 2 when the substrate 2 is seated on the substrate support 104. In certain examples, the second optical axis 406 may be circumferentially offset from the first optical axis 174 about the rotation axis 156. In accordance with certain examples, the third optical axis 408 may be circumferentially offset from the second optical axis 406 about the rotation axis 156. It is also contemplated that, in accordance with certain examples, the third optical axis 408 may be circumferentially offset from both the first optical axis 174 and the second optical axis 406.

It is contemplated that the second pyrometer 402 and the third pyrometer 404 be operatively connected to the upper heat source 106. In this respect, the first pyrometer 110 may be operatively connected to the first upper heater element 162 to control power applied to the first upper heater element 162 to control the heat generated by the first upper heater element 162 and communicated into the upper chamber 148 (shown in FIG. 3) of the chamber body 102 (shown in FIG. 3). The second pyrometer 402 may be operatively connected to the second upper heater element 164 to control power applied to the second upper heater element 164 to control the heat generated by the second upper heater element 164 and communicated into the upper chamber 148 of the chamber body 102 by the second upper heater element 164. The third pyrometer 404 may be operatively connected to the at least one third upper heater element 166 to control the heat generated by the at least one third upper heater element 166 and communicated into the upper chamber 148 of the chamber body 102 by the at least one third upper heater element 166. The thermocouple 112 may be operatively connected to the lower heat source 108 to control heat communicated into the lower chamber 150 of the chamber body 102 to control the heating of the substrate support 104 independent of the heating of the substrate 2 by the upper heat source 106. The operative connection may be through the controller 114. In this respect, the first pyrometer 110 and the thermocouple 112 are connected to the controller 114 by the wired or wireless link 116. In further respect, the second pyrometer 402 and the third pyrometer 404 may also be connected to the controller 114 by the wired or wireless link 116.

The upper surface 4 of the substrate may comprise multiple heating zones. For example, the portion of the upper surface 4 below the first upper heater element 162 may be classified as the first heating zone 410, the portion of the upper surface 4 below the third upper heater element 166 may be classified as the second heating zone 412, and the portion of the upper surface 4 below the second upper heater element 164 be classified as a third heating zone 414. The controller 114 may be configured to (a) assign the first upper heater element 162 to the first heating zone 410, assign the at least one third upper heater element 166 to the second heating zone 412, and assign the second upper heater element 164 to the third heating zone 414. The controller 114 may also be configured to (b) receive the first optical temperature measurement 172 from the first pyrometer 110, receive a second optical temperature measurement 418 from the second pyrometer 402, receive a third optical temperature measurement 420 from the third pyrometer 404. It is contemplated that the controller 114 may be further configured to (c) compare the first optical temperature measurement 172 to a predetermined first upper surface bake temperature 422 for the first heating zone, compare the second optical temperature measurement 418 to a predetermined second upper surface bake temperature 424 for the second heating zone, and compare the third optical temperature measurement 420 with a predetermined third upper surface bake temperature 426 for the third heating zone. When any one of the comparisons indicates that temperature is outside of a predetermined limit from the upper surface bake temperature, the controller 114 may (d) change power applied to the first upper heater element 162, change power applied to the at least one third upper heater element 166, change power applied to the second upper heater element 164, change power applied to the first lower heater element 168 and/or change power applied to the at least one second lower heater element 170.

In certain examples, each of the upper heater elements of the upper heat source 106 may be distributed into one of the first heating zone 410, a second heating zone 412, and a third heating zone 414. For example, three (3) centrally positioned upper heater elements of the upper heat source 106 may be assigned to the first heating zone 410, four (4) of the upper heater elements paired on longitudinally opposite sides of the upper heater elements assigned to the first heating zone 410 may be assigned to the second heating zone 412, and four (4) of the upper heater elements paired and distributed between the upper heater elements of first heating zone 410 and those assigned to the second heating zone 412 may be assigned to the third heating zone 414.

With reference to FIGS. 7-9, the method 700 for removing contaminants from an upper surface (e.g., the upper surface 4) of the substrate (e.g., the substrate 2), e.g., before a material layer (e.g., thin material film) is deposited on the substrate, is shown. As shown in FIG. 7, the method 700 may include supporting a substrate on a substrate support inside an etch chamber (e.g., one of the reactor chambers 100A, 100B, 100C, 100D allocated for performing dry-clean processes) of a semiconductor processing system (e.g., the semiconductor processing system 30 of FIG. 1). For example, the substrate 2 (shown in FIGS. 2, 3, and 5) may be supported by the substrate support 104 (shown in FIG. 4) inside the reactor chamber 100 (shown in FIG. 1), as shown in step 710.

At step 720, the substrate is exposed to an etchant by flowing the etchant as a precursor (e.g., precursor 16) onto or across the substrate (shown in FIG. 2). The etchant may comprise hydrogen radicals, fluorine radicals, and/or chlorine radicals. The etchant may chemically react with the contaminants on the upper surface of the substrate to etch the contaminants away from the upper surface.

At step 730, the substrate may be transferred from the dry etch chamber to a deposition chamber (e.g., one of the reactor chambers 100A, 100B, 100C, 100D allocated for performing material deposition) of the semiconductor processing system for performing steps 740-790. The substrate may be transferred via a substrate transfer chamber (e.g., the substrate transfer chamber 32 in FIG. 1) connecting the etch chamber and the deposition chamber. The substrate transfer chamber may include a robot for transferring substrates between the etch chamber and the deposition chamber.

In some examples, instead of performing steps 710 and 720 to remove contaminates using the dry-clean method, the contaminates may be removed using the wet-clean method outside the silicon processing system. The substrate then may be loaded into a load port of the silicon processing system (e.g., the load ports 38, 40, 42 in FIG. 1) and transferred to the dry etch chamber for performing steps 710 and 720, or to a material deposition chamber for performing steps 740-790. Alternatively, the process may begin at step 730, with prior decontamination of the substrate being performed in separate process or not performed at all.

After the substrate is seated on a substrate support inside the deposition chamber, steps 740-760 may be performed to bake the substrate to remove residual contaminants after the wet-clean process, the dry-clean process, or both, and the contaminants acquired during the transferring of the substrate. After steps 740-760 are performed, steps 770-790 may be performed to deposit a material layer on the substrate.

In step 740, settings for the upper heat source (e.g., the upper heat source 106) of the deposition chamber may be received for the baking process. The received settings may be stored by a controller of the deposition chamber, e.g., stored in the memory 190 by the controller 114. The settings may indicate classifications of heating zones on the upper surface of the substrate, upper heater elements (e.g., upper heater elements 162, 164, 166) of the upper heat source allocated to each heating zone, pyrometers (e.g., pyrometers 110, 402, 404) allocated to each zone, predetermined power to be supplied to each heating zone, and/or a predetermined upper surface bake temperature for each heating zone. In some examples, settings for other environmental conditions within the reactor chamber suitable for contamination removal may be received. For example, settings may be received to flow hydrogen radicals and/or hydrogen gas inside the deposition chamber, and/or to set the atmospheric pressure inside the deposition chamber. The atmospheric pressure inside the deposition chamber may be between 2 to 500 torr, 2 to 300 torr, 4 to 200 torr, or 4 to 80 torr, or 4 to 40 torr, or 4 to 20 torr, or 4 to 10 torr.

In step 750, information about one or more times period for the baking process may be received, and such information about the time period may be stored by the controller of the reactor chamber, e.g., stored in the memory 190 by the controller 114. The information about the time period may indicate how long the heater elements of the upper heat source are to be controlled or for how long heat will be provided to the upper surface of the substrate. The time period may be of any duration, for example, between 4 and 35 seconds, between 5 and 25 seconds, between 5 and 18 seconds, between 5 and 12 seconds, between 5 and 9 seconds, between 4 and 10 seconds, between 10 and 20 seconds, between 20 and 30 seconds, or between about 30 and 35 seconds. Baking the substrate in the order of second may reduce time take to process substrate, and/or increase throughput. In some examples, different time periods may be provided for different heating zones of the upper surface.

In step 760, heat may be provided to the upper surface of the substrate for the time period of step 750 based on the settings received at step 740. The heat may be provided to the upper surface of the substrate with the upper heat source, e.g., the upper heat source 106 (shown in FIG. 5), radiating heat directly to the upper surface. The upper surface may be heated to a temperature between 850° C. and 1100° C. While heat is provided to the upper surface, the deposition chamber may comprise hydrogen gas or radicals, or hydrogen gas or radicals may be flowed onto or across the substrate. Heating the upper surface may induce a chemical reaction between the contaminants on the upper surface of the substrate and hydrogen gas or radicals, such that the contaminants are etched away or removed from the upper surface of the substrate.

As the upper surface of the substrate is heated to a temperature between 850° C. and 1100° C. for a period of 4 to 35 seconds, the temperature of the rest of the portion of the substrate, such as the bulk material forming the substrate, the middle portion, and/or the lower portion, might not reach the temperature of the upper surface. A lower heat source (e.g., the lower heat source 108 shown in FIG. 3) may be kept off or, alternately, may provide enough heat to the substrate to reduce the temperature gradient between the upper surface and the rest of the substrate. While the temperature of the middle portion of the substrate or the bottom surface of the substrate may increase due to heat conduction from the upper surface of the substrate to the rest of the portion of the substrate, the temperature at the middle of the substrate or the bottom surface of the substrate may be substantially lower than the temperature at the upper surface of the substrate. The temperature in the middle of the substrate or the bottom surface of the substrate may also be lower than the thermal budget temperature of the substrate (e.g., a temperature at which dopant or silicon would exhibit migration or alternation for device structures). Increasing the temperature of the substrate to be above the thermal budget temperature may increase the risks of dopant or silicon migration or alternation for device structures, which may affect the electrical properties of the patterned device structures in the substrate. Therefore, the temperature of the middle of the substrate or the bottom surface of the substrate being lower than the thermal budget temperature of the substrate during the baking process of step 760 will reduce the risk of dopant or silicon migration or alternation for device structures.

After the baking process of steps 740-760, steps 770-790 may be performed to deposit a material layer onto the substrate. At step 770, the substrate may be heated to a predetermined material layer deposition temperature. Heat may be provided to the substrate during the deposition of the material layer onto the substrate with the upper heat source (e.g., the upper heat source 106) of the deposition chamber and/or with the lower heat source (e.g., the lower heater element array 108) of the deposition chamber.

At step 780, the substrate may be exposed to a material layer precursor (e.g., the precursor 16 shown in FIG. 2) by flowing the precursor across the substrate. Flowing the material layer precursor across the substrate may include flowing a silicon-containing precursor (e.g., dichlorosilane (H₂SiCl₂) and trichlorosilane (HCl₃Si), and non-chlorinated silicon-containing precursors, such as silane (SiH₄) and/or disilane (Si₂H₆)), a germanium-containing precursor (e.g., GeH₄), a dopant-containing precursor (e.g., boron (B) and/or arsenic (As)), and/or a halide-containing material (e.g., chlorine (Cl), e.g., chlorine (Cl₂) gas and hydrochloric (HCl) acid, as well as fluorine (F), e.g., fluorine (F₂) gas and hydrofluoric (Hf) acid). The precursor may be flown with a purge/carrier gas (e.g., hydrogen (H₂) gas, inert gases such as argon (Ar) gas or helium (He) gas, or nitrogen (N₂) and mixtures thereof).

At step 790, a material layer may be deposited onto the substrate using the material layer precursor of step 780. Depositing the material layer onto the substrate may include epitaxially depositing a silicon-containing material layer or a silicon-germanium material layer on the substrate. The material layer may be doped with phosphorus (P) or arsenic (As).

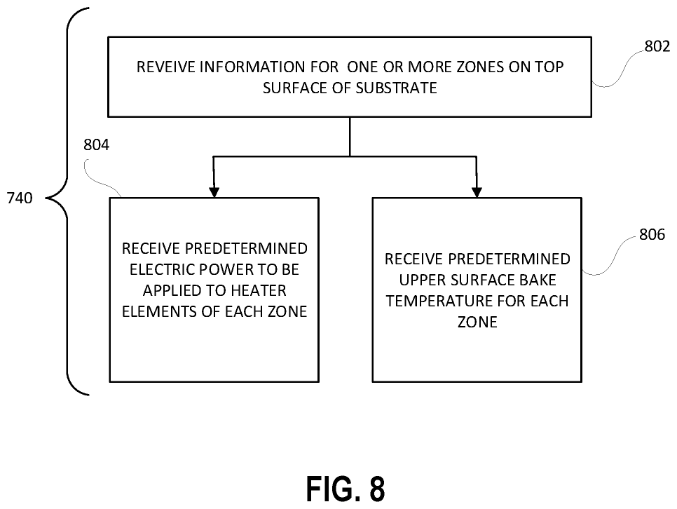

As shown in FIG. 8, step 740 of FIG. 7 may comprise receiving information about one or more heating zones on the upper surface of the substrate in step 802. A pyrometer and/or one or more heater elements of the upper heat source may be allocated to each heating zone. For example, the entire upper surface of the substrate may be considered as one heating zone, and all the heater elements of the upper heat source 106 and/or the pyrometer 110 may be allocated for that heating zone. The upper surface 4 of the substrate may comprise multiple heating zones. As another example, as shown in FIG. 6, the portion of the upper surface 4 below the first upper heater element 162 may be classified as a first heating zone 410, the portion of the upper surface 4 below the third upper heater element 166 may be classified as a second heating zone 412, and the portion of the upper surface 4 below the second upper heater element 164 be classified as a third heating zone 414. The information may indicate that the first upper heater element 162 may be mapped to the first heating zone 410, the third upper heater element 166 may be mapped to the second heating zone 412, and the second upper heater element 164 may be mapped to the third heating zone 414. Additionally, the information may indicate that the first pyrometer 110 is allocated to the first heating zone 410, the second pyrometer 402 is mapped to the second heating zone 412, and/or the third pyrometer 404 is mapped to the third heating zone 414. The information providing the mapping and/or allocation of the pyrometers 110, 402, and 404 and the upper heater elements may be stored by the controller of the deposition chamber (e.g., stored in the memory 190 by the controller 114). While examples herein include a single heating zone or three heating zones on the upper surface of the substrate, the upper surface may be classified into any number of heating zones. Having multiple heating zones may allow tuning the upper surface bake temperature of each heating zone based on the level of contaminants present in that heating zone. For example, a higher upper surface bake temperature may be used in a heating zone that is more likely to have greater amount of contaminants, while a lower upper surface bake temperature may be used for a heating zone with lower amount of contaminants. A single pyrometer may be assigned for multiple heating zones.

In step 804, information may be received about a predetermined amount of electric power that may be supplied to the heater elements of each heating zone. For example, the information may indicate for a single heating zone, the same electric power (e.g., 55% of the maximum applicable power of 10,000 watts) may be applied to all the heater elements of the upper heat source 106. For the example with the first heating zone 410, the second heating zone 412, and/or the third heating zone 414, the information may indicate providing a first power (e.g., 50% of the maximum applicable power of 10,000 watts) to the first upper heater element 162 of the first heating zone 410, a second power (e.g., 45% of the maximum applicable power of 10,000 watts) to the third upper heater element 166 of the second heating zone 412, and/or a third power (e.g., 55% of the maximum applicable power of 10,000 watts) to the second upper heater element 164 of third heating zone 414. The recited power setting of the heater elements are only illustrative, and other power settings may be used and/or remain within the scope of the present disclosure.

Additionally, or alternatively to step 804, step 806 may be performed, where information may be received about a predetermined upper surface bake temperature may be received for one or more heating zones. The predetermined upper surface bake temperature for a heating zone may indicate that the heating zone needs to be heated to the predetermined upper surface bake temperature during the contaminant removal or process of step 760 in FIG. 7. For a single heating zone, for example, the same predetermined upper surface bake temperature (e.g., temperature between 750° C. and 1100° C.) may apply to the entire upper surface of the substrate. In the other example with the first heating zone 410, the second heating zone 412, and the third heating zone 414, the predetermined upper surface bake temperatures may be different for the first heating zone 410, the second heating zone 412, and/or the third heating zone 414 (e.g., 950° C. for the first zone 410, 970° C. for the second heating zone 412, and 940° C. for the third heating zone 414). The predetermined upper surface bake temperatures received at step 806 may be above the threshold temperature required to initiate the thermally induced chemical reaction between the contaminants and hydrogen gas.

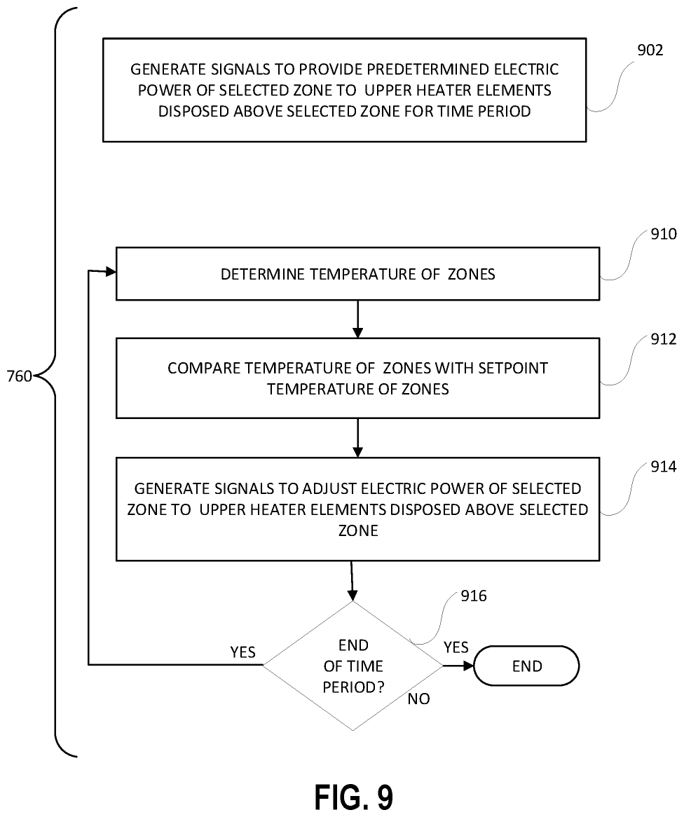

As shown in step 902 of FIG. 9, if predetermined electric powers are provided for the upper heat source, step 760 of FIG. 7 may comprise an open loop configuration where signals may be generated to provide predetermined electric powers to the upper heater elements of the upper heat source. For example, signals may be generated for a single heating zone upper surface to provide the same electric power (e.g., 55% of the maximum applicable power of 10,000 watts) to all the upper heater elements 162. For the example with the first heating zone 410, the second heating zone 412, and/or the third heating zone 414, signals may be generated to provide a first power to the first upper heater element 162 of the first heating zone 410, a second power to the third upper heater element 166 of the second heating zone 412, and/or a third power to the second upper heater element 164 of third heating zone 414. The signals may be generated by the controller of the deposition chamber (e.g., the controller 114). The controller may have discrete control over power applied to each of the upper heater elements of the upper heat source. The signals may indicate to continue providing the predetermined power for a time period (e.g., the time period received at step 750).

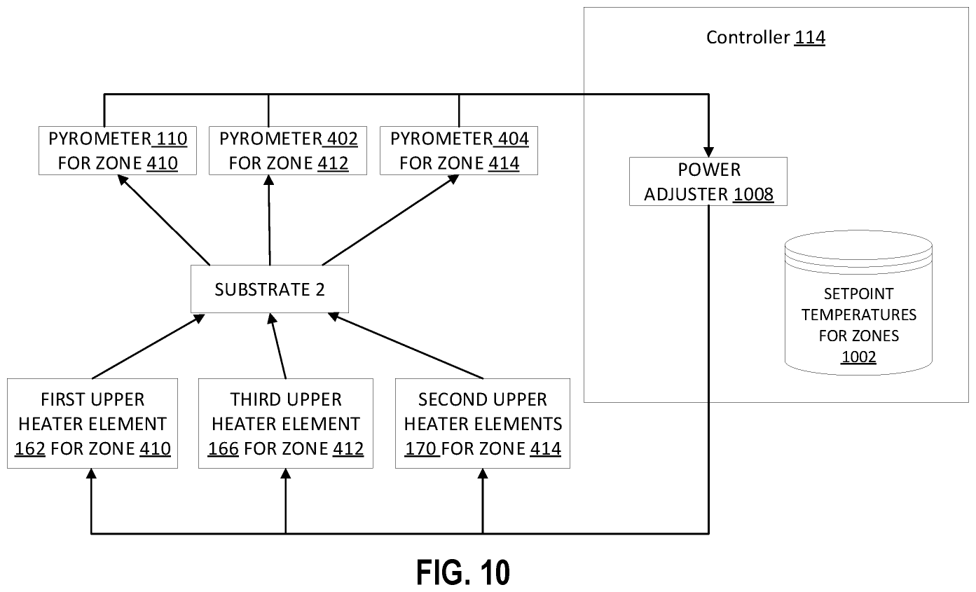

If predetermined upper surface bake temperatures are provided for each heating zone, step 760 of FIG. 7 may comprise a closed-loop configuration where the temperatures of the different heating zones are determined in step 910. For example, as shown in FIG. 10, the controller 114 of the deposition chamber may receive the first optical temperature measurement 172 from the first pyrometer 110 for the first heating zone 410 or for the single heating zone example, receive a second optical temperature measurement 418 from the second pyrometer 402 for the second heating zone 412, and/or receive a third optical temperature measurement 420 from the third pyrometer 404 for the third heating zone 414.

In step 912, the temperatures of the different heating zones may be compared with the predetermined upper surface bake temperatures of the heating zones. For example, as shown in FIG. 10, the controller 114 may comprise a database 902 storing the predetermined upper surface bake temperatures for one or more heating zones. A power adjuster module 1008 may compare the first optical temperature measurement 172 to a predetermined first predetermined upper surface bake temperature for the first heating zone 410, compare the second optical temperature measurement 418 to a predetermined upper surface bake temperature for the second heating zone 412, and/or compare the third optical temperature measurement 420 with a predetermined upper surface bake temperature for the third heating zone 414. The power adjuster module 1008 may be a software module and/or a hardware module that provide closed-loop proportional integral derivative (PID) control over the upper heater elements of the upper heat source.

Referring back to FIG. 9, when any one of the comparisons indicates that a received temperature from a pyrometer assigned to a heating zone is outside of a predetermined limit from the predetermined upper surface bake temperature of the heating zone, signals may be generated to adjust the electric power of the upper heater elements allocated to that heating zone in step 914. For example, the controller 114 may adjust (e.g., increase or decrease) the first power applied to the first upper heater element 162 for the first heating zone 410, adjust the second power applied to the third upper heater element 166 for the second heating zone 412, and/or adjust the third power applied to the second upper heater element 164 for the third heating zone 414. Steps 910, 912, and 914 may be performed in a loop, e.g., until the time period for heating the upper surface of the substrate expires.

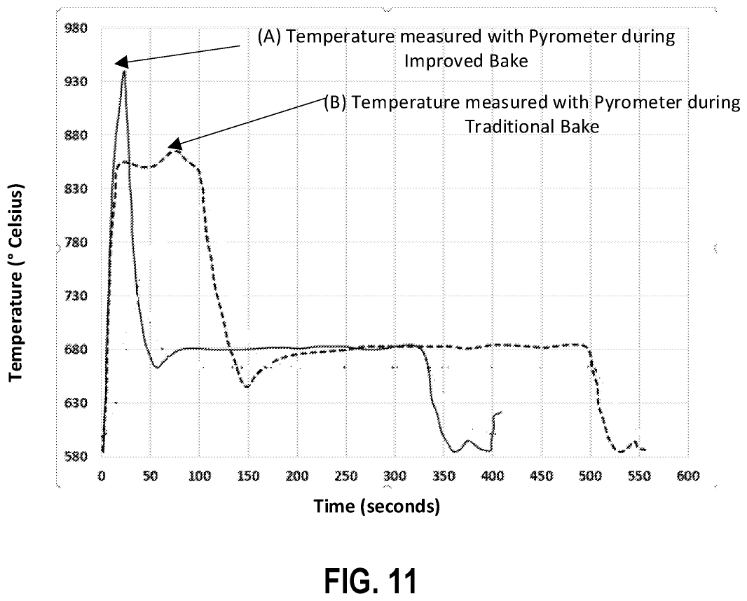

FIG. 11 shows the temperature profile B of a substrate, measured with a pyrometer located above the substrate (e.g., pyrometer 110, 402, or 404) during a traditional bake where both the upper heat source 106 and the lower heat source 108 are turned on to heat the substrate for removal of contaminants from the top substrate of the surface. Profile B indicates the upper surface of the substrate achieves an average temperature of 850° C. when heated for 100 seconds. The area under profile B may correspond to the amount of energy the substrate absorbs during the heating period of the traditional bake for 100 seconds. Profile A shows the temperatures measured by the pyrometer when the improved method described in FIG. 7 is used to remove contaminants from the upper surface of the substrate. The upper heat source 106 is turned on, for example, for 20 seconds such that the temperature of the upper surface reaches 940° C. Profile A indicates the temperature of the upper surface. The area under profile A is relatively smaller than the area under profile B. As energy absorption is lower in the improved bake method for contamination removal, there is less risk of dopant and silicon atom migrations and shape alterations of thin device structures in the substrates. Furthermore, while it takes the upper surface around 50 seconds to cool down to the deposition temperature of 680° C. in the improved bake method, the same cooldown takes 130 seconds for the traditional bake due to the fact that the substrate has absorbed more heat in the traditional bake.

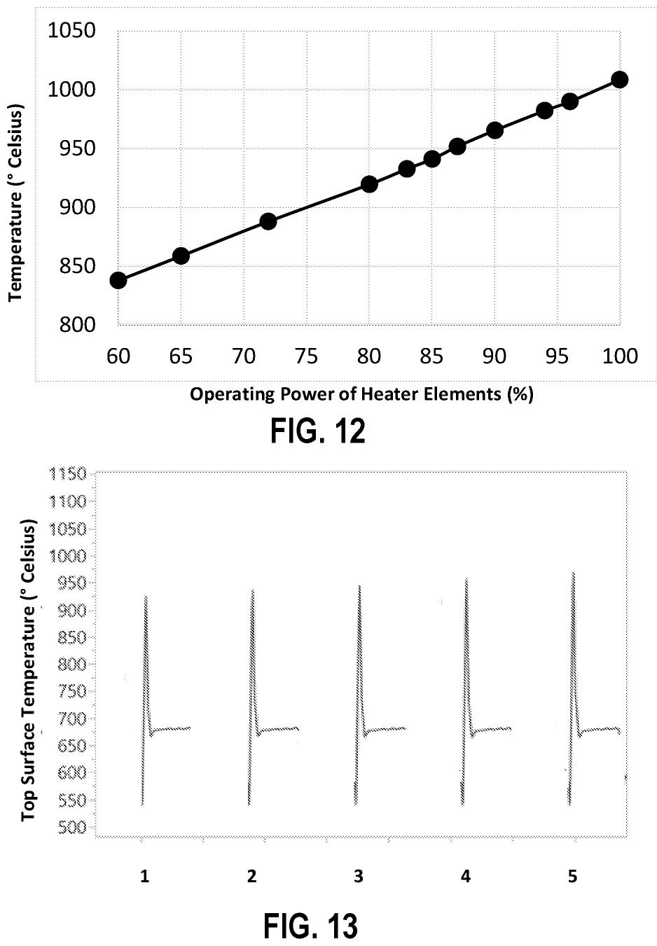

FIG. 12 illustrates that the temperature of the upper surface may be tuned with the amount of power applied to the upper heater elements of the upper heat source 106 (e.g., using open-loop control). For example, for a set period of time (e.g., 20 seconds), the upper surface of a substrate may be heated to a temperature of 840° C. if 60% of the maximum power of 10,000 watts is provided to the upper heater elements of the upper heat source 106, a temperature of 920° C. if 80% of the maximum power of 10,000 watts is provided to the upper heater elements of the upper heat source 106, and a temperature of 1005° C. if 100% of the maximum power of 10,000 watts is provided to the upper heater elements of the upper heat source 106. FIG. 12 indicates that the temperature of the upper surface is directly proportional to the power supplied to the upper heater elements of the upper heat source 106. FIG. 13 illustrates the repeatability of the upper heat source in achieving approximately the same upper surface temperature during the manufacturing process of different substrates (e.g., substrates 1, 2, 3, 4, and 5).

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above. The headings provided herein, if any, are for convenience only and do not necessarily affect the scope or meaning of the devices and methods disclosed herein.

1. A material layer deposition method, comprising:
supporting a substrate in a dry etch chamber;
exposing, in the dry etch chamber, an upper surface of the substrate to an etchant for etching the upper surface;
transferring the substrate from the dry etch chamber to a deposition chamber via a substrate transfer chamber connecting the dry etch chamber and the deposition chamber;
while the substrate is in the deposition chamber:
measuring, with a pyrometer, electromagnetic radiation emitted from the upper surface;
heating at least a portion of the upper surface to a predetermined upper surface bake temperature to remove contaminants from the upper surface, while a bulk material temperature of a bulk material forming the substrate remains less than the predetermined upper surface bake temperature, wherein the heating is with a radiant heat source arranged above the deposition chamber and is based on the measuring with the pyrometer;
after the heating of the upper surface to remove the contaminants, heating the substrate to a predetermined material layer deposition temperature; and
depositing a material layer onto the upper surface.

2. The method of claim 1, wherein the predetermined upper surface bake temperature is above a thermal budget temperature, and wherein electrical properties of patterned structures in the substrate are affected by the bulk material being above the thermal budget temperature.

3. The method of claim 1, wherein the predetermined upper surface bake temperature is between 850° C. and 1100° C.

4. The method of claim 1, wherein the heating of the upper surface comprises heating the upper surface for a time period, and wherein the time period is less than 35 seconds.

5. The method of claim 1, wherein the radiant heat source comprises a plurality of heater elements, and wherein the heating of the upper surface comprises:
determining, based on the measuring with the pyrometer, an upper surface temperature of the upper surface; and
adjusting, based on a comparison of the upper surface temperature with the predetermined upper surface bake temperature, electric power applied to at least one heater element of the plurality of heater elements.

6. The method of claim 5, wherein the heating of the upper surface further comprises:
repeating the determining of the upper surface temperature and the adjusting of the electric power to provide a closed-loop control over the heating of the upper surface.

7. The method of claim 1, wherein the upper surface comprises at least the portion and a second portion, wherein a second predetermined upper surface bake temperature is associated with the second portion, wherein the radiant heat source comprises one or more first heater elements disposed above the portion and one or more second heater elements disposed above the second portion, and wherein the heating the upper surface comprises:
determining, based on the measuring with the pyrometer, a first upper surface temperature of the portion;
determining, based on measuring second electromagnetic radiation emitted from the second portion with a second pyrometer, a second upper surface temperature of the second portion;
based on a comparison of the first upper surface temperature with the predetermined upper surface bake temperature, adjusting first electric power applied to the one or more first heater elements; and
based on a comparison of the second upper surface temperature with the second predetermined upper surface bake temperature, adjusting second electric power applied to the one or more second heater elements.

8. The method of claim 1, wherein the contaminants comprise:
contaminants deposited on the upper surface during the transferring; or
contaminants deposited on the upper surface prior to supporting the substrate in the dry etch chamber.

9. A semiconductor processing system for depositing a material layer, comprising:
a dry etch chamber;
a deposition chamber;
a radiant heat source arranged above the deposition chamber;
a substrate transfer chamber connecting the dry etch chamber and the deposition chamber;
a pyrometer configured to measure electromagnetic radiation emitted from an upper surface of a substrate supported by a substrate support of the deposition chamber; and
one or more controllers configured to:
support the substrate on another substrate support of the dry etch chamber;
expose, in the dry etch chamber, the upper surface of the substrate to an etchant for etching the upper surface;
transfer, via the substrate transfer chamber, the substrate from the dry etch chamber to the deposition chamber;
while the substrate is in the deposition chamber, control, based on a measurement from the pyrometer, the radiant heat source to heat the upper surface to a predetermined upper surface bake temperature to remove contaminants from the upper surface, while a bulk material temperature of a bulk material forming the substrate remains less than the predetermined upper surface bake temperature;
after heating the upper surface to remove the contaminants, heat the substrate to a predetermined material layer deposition temperature; and
deposit a material layer onto the upper surface.

10. The semiconductor processing system of claim 9, wherein the one or more controllers are configured to:
maintain the bulk material temperature to below a thermal budget temperature at which electrical properties of patterned structures in the substrate are affected by the bulk material being above the thermal budget temperature.

11. The semiconductor processing system of claim 9, wherein the predetermined upper surface bake temperature is between 850° C. and 1100° C.

12. The semiconductor processing system of claim 9, wherein the one or more controllers are configured to control the radiant heat source to heat the upper surface to the predetermined upper surface bake temperature within a time period, and wherein the time period is less than 35 seconds.

13. The semiconductor processing system of claim 9, wherein the radiant heat source comprises a plurality of heater elements, and
wherein, to control the radiant heat, the one or more controllers are further configured to:
determine, based on the measurement from the pyrometer, an upper surface temperature of the upper surface; and
adjust, based on a comparison of the upper surface temperature with the predetermined upper surface bake temperature, electric power applied to at least one heater element of the plurality of heater elements.

14. The semiconductor processing system of claim 13, wherein, to control the radiant heat source, the one or more controllers are further configured to:
repeat the determining of the upper surface temperature and the adjusting of the electric power to provide a closed-loop control over the heating of the upper surface.

15. One or more non-transitory computer readable medium storing instructions that, when executed by one or more processors, cause an apparatus to:
support a substrate on a substrate support of a dry etch chamber;
expose, in the dry etch chamber, an upper surface of the substrate to an etchant for etching the upper surface;
transfer the substrate from the dry etch chamber to a deposition chamber via a substrate transfer chamber connecting the dry etch chamber and the deposition chamber;
while the substrate is in the deposition chamber:
measure, with a pyrometer, electromagnetic radiation emitted from the upper surface;
control, based on the measuring with the pyrometer, a radiant heat source, arranged above the deposition chamber, to heat the upper surface to a predetermined upper surface bake temperature to remove contaminants from the upper surface, while a bulk material temperature of a bulk material forming the substrate remains less than the predetermined upper surface bake temperature;
after heating the upper surface to remove the contaminants, heat the substrate to a predetermined material layer deposition temperature; and
deposit a material layer onto the upper surface.

16. The one or more non-transitory computer readable medium of claim 15, wherein the instructions, when executed by one or more processors, cause the apparatus to:
maintain the bulk material temperature to below a thermal budget temperature at which electrical properties of patterned structures in the substrate are affected by the bulk material being above the thermal budget temperature.

17. The one or more non-transitory computer readable medium of claim 15, wherein the predetermined upper surface bake temperature is between 850° C. and 1100° C.

18. The one or more non-transitory computer readable medium of claim 15, wherein the instructions, when executed by the one or more processors, cause the apparatus to:
control the radiant heat source for a time period, and wherein the time period is less than 35 seconds.

19. The one or more non-transitory computer readable medium of claim 15, wherein the radiant heat source comprises a plurality of heater elements, and
wherein the instructions, when executed by the one or more processors control the radiant heat source by causing the apparatus to:
determine, based on the measuring with the pyrometer, an upper surface temperature of the upper surface; and
adjust, based on a comparison of the upper surface temperature with the predetermined upper surface bake temperature, electric power applied to at least one heater element of the plurality of heater elements.

20. The one or more non-transitory computer readable medium of claim 19, wherein the instructions, when executed by the one or more processors, further control the radiant heat source by causing the apparatus to:
repeat the determining of the upper surface temperature and the adjusting the electric power to provide a closed-loop control over the heating of the upper surface.
